(19) United States
(12) Patent Application Publication
(10) Pub. No.: US 2013/0154453 A1
(43) Pub. Date: Jun. 20, 2013

(54) ENCLOSURE FOR ACCOMMODATING DEVICES, IN PARTICULAR ELECTRONIC DEVICES, ELEMENTS AND THE LIKE

(71) Applicant: Rittal GmbH & Co. KG, Herborn (DE)

(72) Inventor: Rolf Benner, Herborn (DE)

(73) Assignee: Rittal GmbH & Co. KG, Herborn (DE)

(21) Appl. No.: 13/688,370

(22) Filed: Nov. 29, 2012

(30) Foreign Application Priority Data
Dec. 15, 2011 (DE) 102011056463.2

(51) Int. Cl. H05K 5/02

(52) U.S. Cl. CPC H05K 5/0217
USPC 312/223.1

(57) ABSTRACT

An enclosure for accommodating electronic devices, elements and the like comprises a base plate and side walls rising therefrom. An insert element joining the side walls is installed in the contact region between two adjacent side walls, and the respective free edges of the side walls are retained force- or form-fit within holding grooves of the insert element.

### BACKGROUND OF THE INVENTION

The invention relates to an enclosure for accommodating devices, in particular electronic devices, elements and the like comprising a base plate and side walls rising therefrom, wherein an insert element joining the side walls is installed in the contact region between two adjacent side walls.

It is known to use, for example in communication and control technology, enclosures or small control cabinets, respectively, which accommodate, for example, sensors together with an electronic evaluation circuit, which in turn are or can be provided with connecting, display, fastening and/or actuating elements. Moreover, other substantially self-sustaining electronic devices and elements may be accommodated in small enclosures of this type. Those small enclosures may be accommodated outside or within a larger switchgear cabinet and may be adapted to customer needs.

A switchgear cabinet comprising a framework is for example known from WO 2010/121588 A2. In order to achieve a high strength and loading capacity of the framework and to realize virtually unlimited dimensions within a short period of time, bars are provided which comprise an outer bar having an open profile. The open region of the outer bar facing inwardly is covered by an inner bar and connected thereto by means of a rivet connection, which inner bar abuts outwardly two sides of the outer bar and comprises at least a bend serving as a supporting surface for a wall surface.

If smaller, self-sustaining control cabinets or enclosures, respectively, are to be realized, it is known to build small enclosures from metal sheets, wherein the side walls, the rear wall, the bottom and the cover part made from metal sheet are welded together along their contact edges and are subsequently grinded. In order to provide, for example, mounting supports for devices, elements and the like within the small enclosure, for example bolts and mounting brackets are attached by means of spot welding. Door hinges and closures are mounted on the small enclosure. The construction of small control cabinets or enclosures, respectively, of this type requires complex manufacture, in particular because of the required welding work.

Accordingly, when building small enclosures, corner connectors are used which are plugged into the associated profile walls or are screwed thereto. An example is shown in DE 103 00 418 A1, where the corner connector is provided with webs in sections which engage insert grooves of the wall profile. Boards and other devices are then mounted to the wall profiles.

It is the object of the invention to disclose an enclosure of the type mentioned in the introductory which is made up simple and has few individual parts and allows simple accommodation of electronic devices, elements and the like.

### SUMMARY OF THE INVENTION

This object of the invention is solved by an enclosure for accommodating electronic devices, elements and the like, comprising a base plate and side walls rising therefrom, wherein an insert element joining the side walls is installed in the contact region between two adjacent side walls, wherein respective free edges of the side walls are retained force- or form-fit within holding grooves of the insert element.

According to the invention, it is provided that respective free edges of the side walls are retained force- or form-fit within holding grooves of the insert element. Thus, the insert element may be moved over the free edges of the side walls in a simple way, the edges being received within the holding grooves and guided therein during assembly. In order to create room for the insert element and to allow easy introduction, the side walls may at least partly be provided with recesses in the contact region. The width of the recesses depends on size and shape of the insert element. Accordingly, a very simple manufacturing process for an enclosure is provided which does no longer require welding and a subsequent finishing of the welding seams, e.g. by grinding.

In many applications, a box-like enclosure is appropriate where the side walls are perpendicular to another and further perpendicular to the base plate. However, the invention also allows building basin-like structures arranged at an angle to another or with the bottom, respectively, which is different from 90°, in particular is larger than 90°.

In an advantageous embodiment of the invention, however, the insert is formed as an optionally rounded rectangular profile, where the holding grooves are provided at adjoining sides of the insert element. Further, a circular cylindrical profile or a profile having oval cross-section are conceivable. Designs of that type are exceptionally strong. In particular, the insert element may be manufactured from plastic. Accordingly, the insert element may be manufactured exceptionally easy and is easy to machine. By forming roundings in the region of the edges, the design may be optimized. Additional possibilities of designing are forming of contours and/or colored design elements.

Further preferred, the insert element may comprise part holding grooves open toward the interior of the enclosure which extend spaced apart from another parallel to the base plate. It is further preferred that the part holding grooves overlap at edges of adjoining sides of the insert element. The part holding grooves serve to accommodate electronic devices or elements, in particular to accommodate mounting plates for such devices or elements. If, for example, the four vertical edge regions of the enclosure are provided with insert elements of this type, the mounting plates may be inserted and retained in part holding grooves respectively arranged on the same level at each insert element.

In order to additionally fasten the devices or elements or the mounting plates, respectively, a plurality of mounting holes may be provided near the part holding grooves which are arranged along the edge of adjoining sides alternately with the part holding grooves and spaced apart therefrom. By means of suitable screw connections, the mounting plate supported in the part holding grooves can be safely fixed. In particular, the mounting holes may be arranged on the adjoining sides of the insert element equidistantly to the edge of the adjoining sides. Accordingly, a pre-defined pattern is created which simplifies interior fitting of the enclosure.

In order to attach, for example, the base plate or a cover part to the inserted insert elements, the free ends of the insert elements may respectively be abutted against the base plate and the cover part which respectively comprise at least one mounting hole for mounting the base plate or the cover part, respectively. For the purpose of easy fixing, the base plate and the cover part may comprise throughbores, respectively corresponding to the mounting holes at the free ends of the insert element. By means of simple screw connection, base plate and cover part of the enclosure may be assembled in a simple way, thus avoiding a weld connection.

Such a mounting hole, however, may also fix a further component, for example a coupling piece or a locking or closure piece.

According to a preferred embodiment of the invention, a coupling piece fixed at a free end of the insert element is provided, where sleeves for receiving hinge pins or locking bolts are formed. A door, for example, may be suspended in these sleeves and may be closed. The coupling piece may also be integral with the insert element.

According to a further embodiment, the coupling piece is contoured to form a support surface for a door, a cover part or a further component.

It is particularly preferred that the base plate is integral with at least one of the side walls, in particular preferably with all side walls. In this way, an enclosure is formed where the side walls are bent with respect to the base plate. That enclosure may be fabricated in a punching and subsequent bending process, so that assembly of the enclosure by using the insert element is considerably simplified.

### BRIEF DESCRIPTION OF THE DRAWINGS

The invention is explained in detail below with the aid of the appended drawings which are not necessarily to scale. It is shown in:

FIG. 1 in a schematic and perspective view the edge region of an enclosure and an insert element according to a preferred embodiment of the present invention;

FIG. 2 another embodiment of an insert element in a perspective bottom view;

FIG. 3 the insert element of FIG. 2 in a perspective top view;

FIG. 4 the insert element of FIG. 2 in a side view;

FIG. 5 an enclosure with door constructed according to the principles of the invention in a partly exploded view, and

FIG. 6 the enclosure of FIG. 5 in an assembled state.

### DETAILED DESCRIPTION OF THE INVENTION

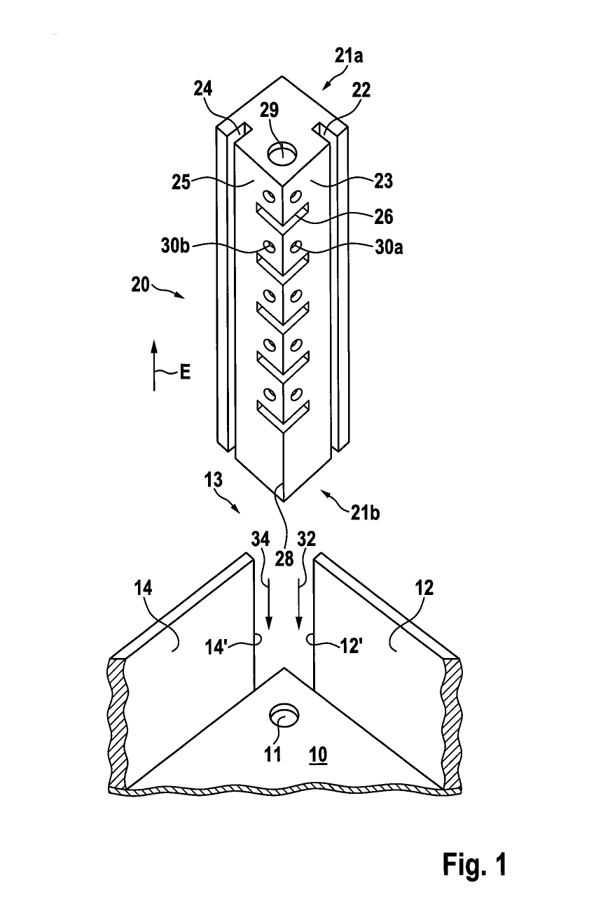

FIG. 1 shows, in a schematic and perspective view, the edge region of an enclosure, wherein two side walls 12, 14 which are bent with respect to a base plate 10, are to be joined with the aid of an insert element 20. In order to receive insert element 20, side wall 12 comprises a recess 32 in a contact region 13, side wall 14 comprises a recess 34 in contact region 13. A throughbore 11 is provided in base plate 10. Side walls 12, 14 may be perpendicular to base plate 10, as illustrated, but can also be at an angle of more than 90° to form a basin-like structure.

The insert element, here shaped as a rectangular profile, the edges thereof optionally being rounded, comprises holding grooves 22, 24 for the free edges 12′, 14′ of side walls 12, 14 in a direction of extension according to arrow E. If a basin-like structure is intended, shaping of the insert element and arrangement of holding grooves, respectively, should be adapted accordingly. Holding grooves 22, 24 are formed at adjoining sides 23 and 25 of insert element 20. In order to simplify interior fitting of the enclosure, insert element 20 further comprises five part holding grooves 26 in the illustrated embodiment, which are open towards the interior of the enclosure. Part holding grooves 26 are arranged vertically one above the other and equidistantly in the direction of extension of the insert element 20 according to arrow E. Part holding grooves 26 are formed at an edge 28 of adjoining sides 23, 25 of insert element 20 and extend substantially perpendicular to the direction of extension E of insert element 20. Above each part holding groove, two mounting holes 30a and 30b are respectively provided. First mounting hole 30a is provided at side 23 of insert element 20 where holding groove 22 for side wall 12 extends. Second mounting hole 30b is arranged at side 25 of insert element 20 where wall holding groove 24 for side wall 14 extends. Free end 21a of insert element 20 may be abutted against a cover part, not shown here, or a door, for example. Free end 21b of insert element 20 may be abutted against base plate 10. Free ends 21a, 21b of insert element 20 each comprise a mounting hole 29, FIG. 1 showing only mounting hole 29 at upper free end 21a of insert element 20. Mounting hole of lower free end 21b (not shown here) of insert element 20 corresponds to the throughbore 11 in base plate 10, when insert element 20 is inserted, through which a screw bolt may be passed and introduced into the mounting hole and screwed therein.

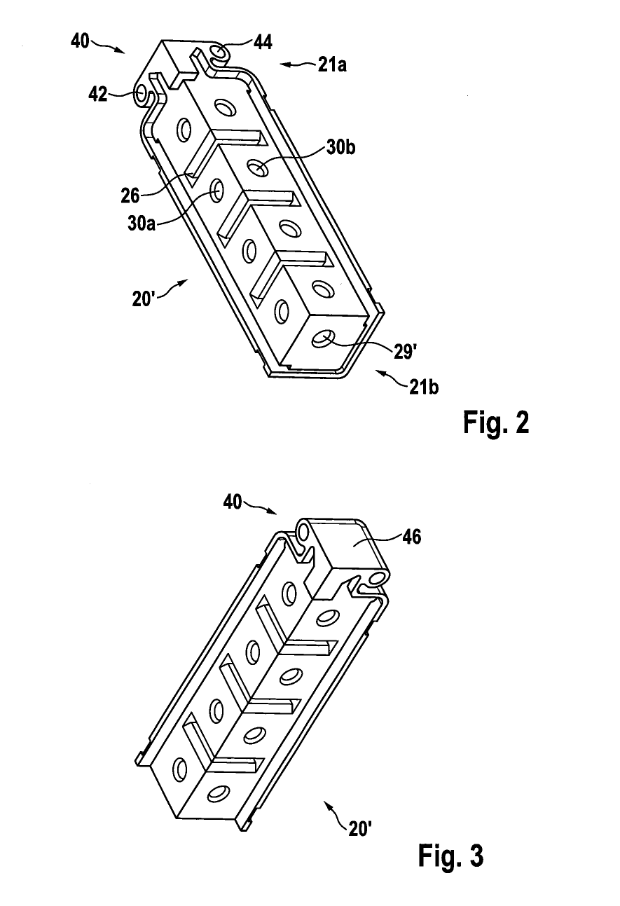

FIG. 2 shows another embodiment of an insert element 20′ according to the present invention in a perspective bottom view. Different from the insert element 20 of FIG. 1, only three part holding grooves 26 are provided in insert element 20′, where mounting holes 30a, 30b are arranged not only between two neighboring part holding grooves 26, but also between a respective part holding groove 26 and free end 21a or 21b, respectively, of insert element 20′. A mounting hole 29′ may be recognized at free end 21b. A coupling piece 40 is provided at free end 21a of insert element 20 and is fixed thereto, having sleeves 42, 44, which are intended to receive hinge pins, as will be explained in detail below.

Coupling piece 40 may be designed for example such that it comprises a post (not visible here) engaging force-fit into mounting hole 29 (FIG. 1). Alternatively, coupling piece 40 can be integral with insert element 20′.

FIG. 3 shows insert element 20′ of FIG. 2 in a perspective top view. Coupling piece 40 is contoured to form a supporting surface 46 against which a door, a cover part or even a further component may be abutted.

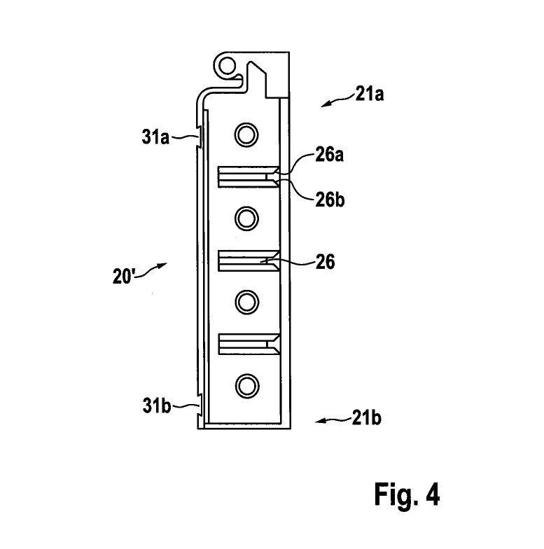

FIG. 4 shows insert element 20′ of FIG. 2 in a side view. Each part holding groove 26 is provided with opposed tapered edges 26a, 26b facilitating introduction, for example, of mounting plates. Insert element 20′ further comprises an undercut groove 31a, 31b arranged at those sides facing away from the interior of the enclosure in an assembled state.

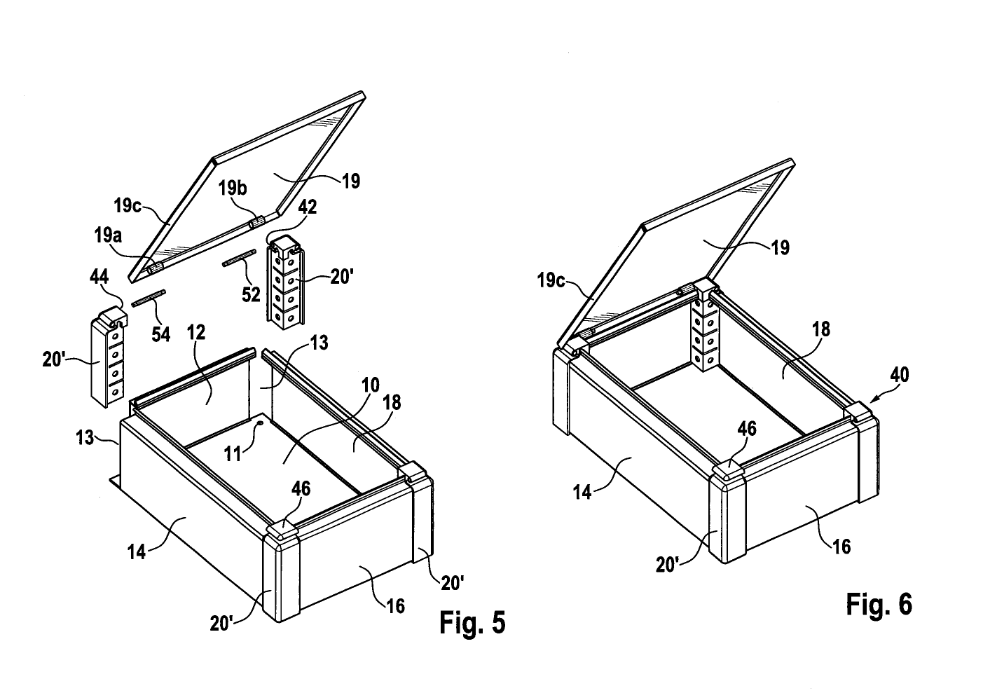

FIG. 5 shows an embodiment of an enclosure according to the present invention in a partly exploded illustration. Four side walls 12, 14, 16, 18 are vertically bent with respect to a base plate 10, wherein side walls 14 and 16 or 16 and 18, respectively, are joined by an insert element 20′. Two additional insert elements 20′ are provided for joining side walls 12 and 14 or 12 and 18, respectively, which are prepared to receive a door 19. To this end, a hinge pin 52 or 54, respectively, is inserted into sleeve 42 of one of insert pieces 20′ and into sleeve 44 of the other insert element 20′ or coupling piece 40, respectively, which is fixed thereto. Corresponding sleeves 19a, 19b are provided at door 19 into which the free ends of hinge pins 52, 54 protruding beyond the respective coupling piece 40 are inserted. Finally, both insert elements 20′ are brought into contact region 30 and moved over the free edges of side walls 12, 14 or 12, 18, respectively. If needed, insert elements 20′ may be fixed at base plate 10 by means of a screw, a bolt or the like which is guided through throughbore 11.

FIG. 6 shows the enclosure with door 19 in an assembled state. Closed door 19 can overlap the accordingly contoured free edges of at least side walls 14, 16, 18 with flanged peripheral edges 19c and abut against supporting surfaces 46 of insert elements 20′. It will be understood that coupling pieces 40 or regions thereof which do not need to receive hinge pins, may be solid and in particular do not need to include sleeves.

The features of the invention disclosed in the previous description, in the drawings and in the claims may be material for realizing the invention, either individually or in any combination thereof.

What is claimed is:

1. An enclosure for accommodating electronic devices, elements and the like, comprising a base plate and side walls rising therefrom, wherein an insert element joining the side walls is installed in the contact region between two adjacent side walls, wherein respective free edges of the side walls are retained force- or form-fit within holding grooves of the insert element.

2. The enclosure of claim 1, wherein the insert element is formed as a circular cylindrical profile, a profile having oval cross-section or a rectangular profile, wherein the holding grooves are formed in sides adjoining each other.

3. The enclosure of claim 2, wherein the rectangular profile comprises at least one rounded edge.

4. The enclosure of claim 1, wherein the insert element comprises part holding grooves which are open towards the interior of the enclosure and extend spaced apart from another parallel to the base plate.

5. The enclosure of claim 4, wherein the part holding grooves overlap an edge of adjoining sides of the insert element.

6. The enclosure of claim 4, wherein the insert piece comprises mounting holes alternately positioned with the part holding grooves and spaced apart therefrom along the edge of adjoining sides.

7. The enclosure of claim 1, wherein the free ends of the insert element respectively comprise at least one mounting hole for mounting the base plate or a cover part, a door or a further component.

8. The enclosure of claim 7, wherein the base plate comprises through bores corresponding to the mounting hole of the associated free end of the insert element.

9. The enclosure of claim 7, wherein a coupling piece fixed at a free end of the insert element is provided, on which sleeves for receiving hinge pins or locking pins are formed.

10. The enclosure of claim 7, wherein the coupling piece is contoured to form a supporting surface for a door, a cover part or a further component.

11. The enclosure of claim 1, wherein the base plate is integral with at least one of the side walls.

12. An insert element provided for an enclosure according to claim 1.
